(19) United States
(12) Patent Application Publication
(10) Pub. No.: US 2010/0270643 A1
(43) Pub. Date: Oct. 28, 2010

(54) Semiconductor device and layout method therefor

(75) Inventor: Takayuki Iwaki, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/662,149

(22) Filed: Apr. 1, 2010

(30) Foreign Application Priority Data
Apr. 23, 2009 (JP) 2009-104832

(51) Int. Cl. H01L 29/92; H01L 21/02

(52) U.S. Cl. 257/532; 438/396; 438/666; 257/E29.343; 257/E21.011

(57) ABSTRACT

Provided is a semiconductor device including: an MIM capacitor that includes a lower electrode, an upper electrode, and a capacitor insulating film formed between the lower electrode and the upper electrode; a first via hole that connects to the lower electrode and extends in a normal upward direction of a principal surface of the lower electrode; a second via hole that connects to the upper electrode and extends in a normal upward direction of a principal surface of the upper electrode; and a plurality of lower wiring lines that are formed under the lower electrode, in which formation areas of the first and second via holes overlap formation areas of the plurality of lower wiring lines when viewed in the normal direction of the principal surface of the upper electrode.

### INCORPORATION BY REFERENCE

This application is based upon and claims the benefit of priority from Japanese patent application No. 2009-104832, filed on Apr. 23, 2009, the disclosure of which is incorporated herein in its entirety by reference.

### BACKGROUND

1. Field of the Invention

The present invention relates to a semiconductor device and a layout method therefor, and more particularly, to a semiconductor device including an MIM capacitor and a layout method therefor.

2. Description of Related Art

In recent years, MIM (Metal-Insulator-Metal) decoupling capacitors have been mounted on LSIs (Large Scale Integration) in order to decrease noise. Further, MIM capacitors are already widely used as memory devices. Therefore, MIM capacitors are of increasing importance as devices mounted on LSIs.

FIG. 8 is a schematic cross-section view illustrating a semiconductor device including an

MIM capacitor disclosed in FIG. 1 of Japanese Unexamined Patent Application Publication No. 2002-353328. The semiconductor device includes a lower interlayer insulating film 1, a lower electrode 2B, a capacitor insulating film 3A, an upper electrode 4, an antireflection film 6, via holes 7B, 7C, and 7D, an interlayer insulating film 8, upper wiring lines 9B and 9C, and a lower wiring line 11. The MIM capacitor is made of the lower electrode 2B, the capacitor insulating film 3A, and the upper electrode 4. The upper electrode 4 connects to the upper wiring line 9C through the via holes 7C and 7D. The lower electrode 2B connects to the upper wiring line 9B through the via hole 7B. The lower electrode 2B also connects to the lower wiring line 11.

By the way, in order to evaluate the effect of MIM capacitors, especially decoupling capacitors, the evaluation may be performed while changing the number of mounted MIM capacitors. Further, only the number of mounted MIM capacitors may be changed in the actual product according to the product specification.

In general, a mask and a mask process for forming MIM capacitors are simply omitted in the case of mounting no MIM capacitor. In this case, via holes to connect to MIM capacitors are formed by using a mask and a mask process for forming via holes of other circuits. Therefore, the via hole forming process cannot be omitted.

### SUMMARY

The present inventor has found a problem as described below. In the case of mounting no MIM capacitor, the via holes, which are arranged for connecting to an upper electrode or a lower electrode of a MIM capacitor, may be formed in an area with no lower wiring line. Therefore, these via holes may connect to a non-targeted wiring line with a different voltage. This causes a process problem or makes it impossible to perform characteristics evaluation.

For example, referring to FIG. 8, the lower wiring line 11 is not formed in the lower extension of the longitudinal direction of the via holes 7C and 7D that connect to the upper wiring line 9C. If a semiconductor device having no MIM capacitor is produced by using a layout mask for this via hole layer (via hole layout mask), the via holes 7C and 7D are formed in the area without the lower wiring line 11, which causes a process problem. In order to avoid this problem, it is necessary to change the layout of via holes or to make a new mask. However, this leads to an increase in time and cost.

A first exemplary aspect of the present invention is a semiconductor device including: an MIM capacitor that includes a lower electrode, an upper electrode, and a capacitor insulating film formed between the lower electrode and the upper electrode; a first via hole that connects to the lower electrode and extends in a normal upward direction of a principal surface of the lower electrode; a second via hole that connects to the upper electrode and extends in a normal upward direction of a principal surface of the upper electrode; and a plurality of lower wiring lines that are formed under the lower electrode, in which formation areas of the first and second via holes overlap formation areas of the plurality of lower wiring lines when viewed in the normal direction of the principal surface of the upper electrode.

A second exemplary aspect of the present invention is a layout method for a semiconductor device, the semiconductor device including: an MIM capacitor that includes a lower electrode, an upper electrode, and a capacitor insulating film formed between the lower electrode and the upper electrode; a first via hole that connects to the lower electrode and extends in a normal upward direction of a principal surface of the lower electrode; a second via hole that connects to the upper electrode and extends in a normal upward direction of a principal surface of the upper electrode; and a plurality of lower wiring lines that are formed under the lower electrode, the layout method including: forming the first and second via holes to overlap the plurality of lower wiring lines when viewed in the normal direction of the principal surface of the upper electrode.

The lower wiring lines are located in the lower extension of the longitudinal direction of the first and second via holes. Therefore, regardless of whether MIM capacitors are mounting or not, the same via hole layout mask can be used to produce the first and second via holes.

According to an exemplary aspect of the present invention, it is possible to provide a semiconductor device that can be evaluated efficiently while changing the number of mounted MIM capacitors, and a layout method therefor.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a schematic cross-section view illustrating a semiconductor device according to a first exemplary embodiment of the present invention;

FIG. 2 is a schematic cross-section view illustrating a semiconductor device including no MIM capacitor;

FIG. 3 is a schematic cross-section view illustrating a semiconductor device including no MIM capacitor according to a comparative example;

FIG. 4 is a plan layout diagram illustrating the semiconductor device according to the first exemplary embodiment of the present invention;

FIG. 5 is a plan layout diagram illustrating upper wiring lines 106b and 106c overlapping FIG. 4;

FIG. 6 is a plan layout diagram illustrating a semiconductor device including no MIM capacitor;

FIG. 7 is a plan layout diagram illustrating a semiconductor device according to a second exemplary embodiment of the present invention; and

FIG. 8 is a schematic cross-section view illustrating a semiconductor device including an MIM capacitor disclosed in FIG. 1 of Japanese Unexamined Patent Application Publication No. 2002-353328.

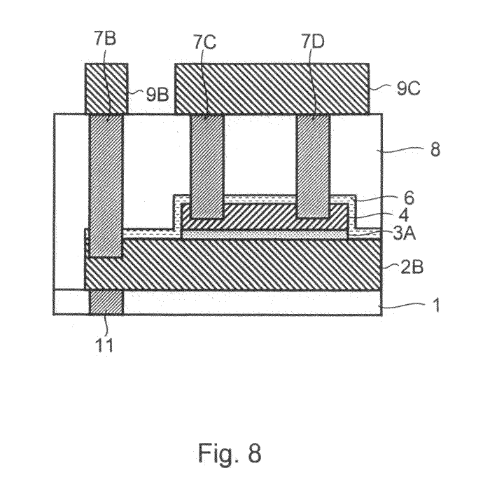

### DETAILED DESCRIPTION OF THE EXEMPLARY EMBODIMENTS

Exemplary embodiments of the present invention will be described in detail below with reference to the accompanying drawings. Note that the present invention is not limited to exemplary embodiments described below. The following descriptions and drawings are simplified as appropriate to clarify the explanation.

[First Exemplary Embodiment]

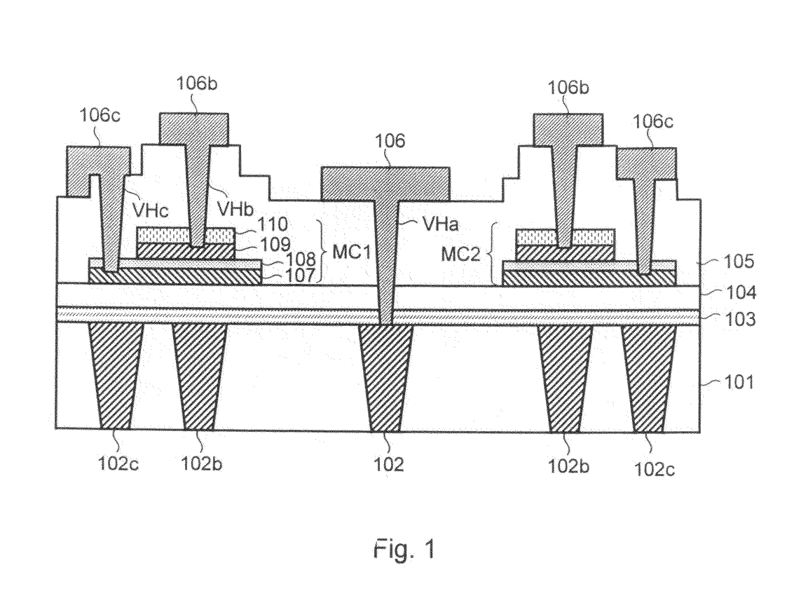

FIG. 1 is a schematic cross-section view illustrating a semiconductor device according to a first exemplary embodiment of the present invention. The semiconductor device includes a first interlayer insulating film 101, lower wiring lines 102, a cap layer 103, a second interlayer insulating film 104, a third interlayer insulating film 105, upper wiring lines 106, and MIM capacitors MC1 and MC2. The MIM capacitors MC1 and MC2 each include a lower electrode 107, a capacitor insulating film 108, an upper electrode 109, and a hard mask layer 110.

As shown in FIG. 1, the first interlayer insulating film 101 is composed of Si0₂, for example, and includes the lower wiring lines 102 composed of Cu, for example. On the first interlayer insulating film 101, the cap layer 103, which is composed of SiC, SiCN, or SiN with about 70-100 nm thickness, for example, is formed. On the cap layer 103, the second interlayer insulating film 104 composed of SiO₂ with about 400 nm thickness, for example, is formed.

The lower electrode 107, which constitutes the MIM capacitors MC1 and MC2, is formed on the second interlayer insulating film 104. The lower electrode 107 is composed of Ti, TiN, Ta, or TaN with about 100-150 nm thickness, for example. The capacitor insulating film 108 is formed on the lower electrode 107. The capacitor insulating film 108 is composed of SiO₂, SiN, Ta₂O₅, or HfO₂ with about 10-50 nm thickness, for example. The upper electrode 109 is formed on the capacitor insulating film 108. The upper electrode 109 is formed with a material and thickness similar to those of the lower electrode 107. The hard mask layer 110 is formed on the upper electrode 109. The hard mask layer 110 is composed of SiN with about 100-200 nm thickness, for example. A via hole VHb is formed above the upper electrode 109 by etching. In order to decrease the etching rate, the hard mask layer 110 is formed.

The third interlayer insulating film 105 composed of SiO₂, for example, is formed to cover the MIM capacitors MC1 and MC2. The upper wiring lines 106 composed of Al, for example, are formed on the third interlayer insulating film 105. Here, in FIG. 1, the third interlayer insulating film 105 covering the MIM capacitors MC1 and MC2 is not planarized. Therefore, the upper wiring lines 106 are assumed to be composed of Al. Needless to say, if the third interlayer insulating film 105 is planarized, the upper wiring lines 106 may be composed of Cu, for example.

An upper wiring line 106c of the upper wiring lines 106 connects to the lower electrode 107, which constitutes the MIM capacitors MC1 and MC2, through a via hole VHc. Further, in the lower extension of the longitudinal direction of the via hole VHc, a lower wiring line 102c with the same voltage as the lower electrode 107 is formed.

An upper wiring line 106b of the upper wiring lines 106 connects to the upper electrode 109, which constitutes the MIM capacitors MC1 and MC2, through a via hole VHb. Further, in the lower extension of the longitudinal direction of the via hole VHb, a lower wiring line 102b with the same voltage as the upper electrode 109 is formed.

The upper wiring line 106 shown in the center of FIG. 1 directly connects to the lower wiring line 102 through a via hole VHa. The lower wiring line 102 directly connecting to the upper wiring line 106 through the via hole VHa is the lower wiring line 102b with the same voltage as the upper electrode 109, or the lower wiring line 102c with same voltage as the lower electrode 107. Here, inside the via holes VHa, VHb, and VHc, wiring lines are integrally formed with the upper wiring line 106.

As described above, in the first exemplary embodiment, the lower wiring lines 102b with the same voltage as the upper electrodes 109 are formed in the lower extension of the longitudinal direction of all the via holes VHb that connect the upper wiring lines 106b to the upper electrodes 109. In the similar manner, the lower wiring lines 102c with the same voltage as the lower electrodes 107 are formed in the lower extension of the longitudinal direction of all the via holes VHc that connect the upper wiring lines 106c to the lower electrodes 107.

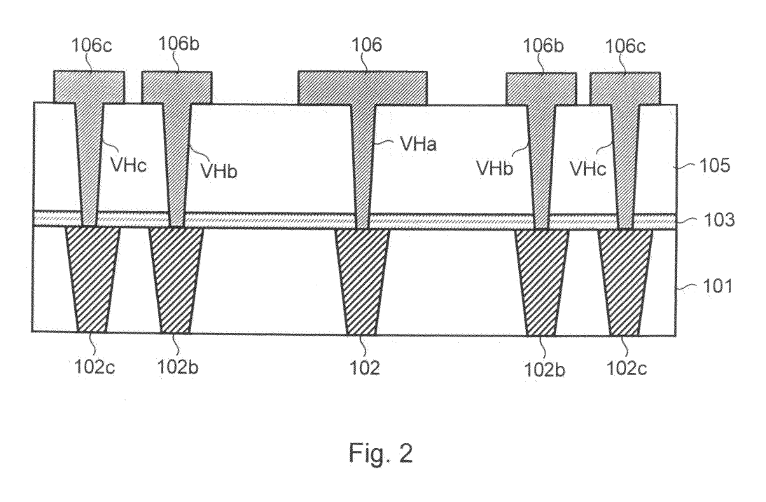

FIG. 2 is a schematic cross-section view illustrating a semiconductor device including no. MIM capacitor. As shown in FIG. 2, even in the case of producing the semiconductor device with no MIM capacitor by using the same via hole layout mask as the semiconductor device with MIM capacitors, the via hole VHb is to connect to the lower wiring line 102b with the same voltage, or the via hole VHc is to connect to the lower wiring line 102c with the same voltage. Therefore, there is no process problem and characteristics evaluation can be performed. In other words, it is possible to provide a semiconductor device that can be evaluated efficiently while changing the number of mounted MIM capacitors.

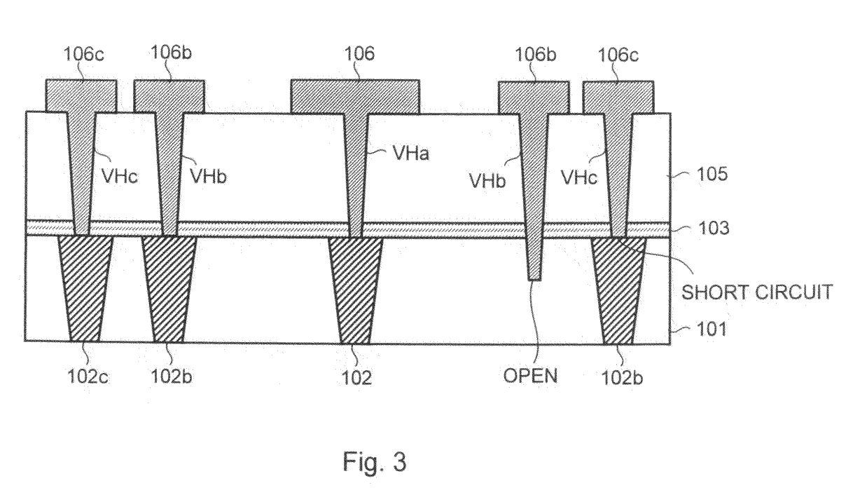

On the other hand, FIG. 3 is a schematic cross-section view illustrating a semiconductor device including no MIM capacitor according to a comparative example. On the right side of FIG. 3, the lower wiring line 102b is not formed in the lower extension of the longitudinal direction of the via hole VHb, which causes a process problem. Further, the upper wiring line 106c connects to the lower wiring line 102b in the different voltage through the via hole VHc, which causes a short circuit.

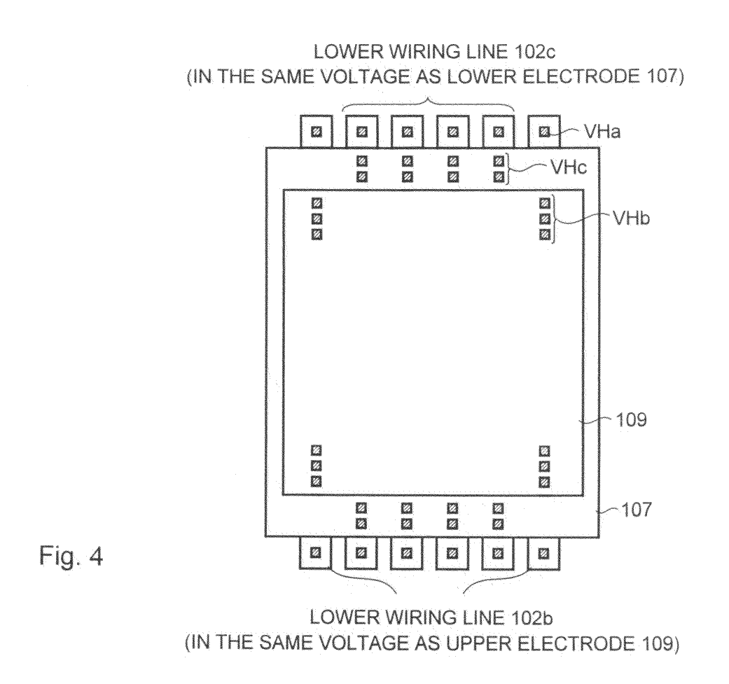

FIG. 4 is a plan layout diagram illustrating a semiconductor device according to the first exemplary embodiment of the present invention. FIG. 4 shows a position relation among the lower wiring line 102, the lower electrode 107, the upper electrode 109, and the via holes VHa, VHb, and VHc when viewed in the normal direction of the principal surface of the upper electrode 109 and lower electrode 107. In the top and bottom direction of FIG. 4, six lower wiring lines 102 are formed. Above lower wiring lines 102, the lower electrode 107 is formed. Above the lower electrode 107, the upper electrode 109 is formed. Here, both of the lower electrode 107 and the upper electrode 109 constitute an MIM capacitor.

Further, above all the lower wiring lines 102, the via hole VHa that directly connects the lower wiring line 102 to the upper wiring line 106 is positioned. In other words, when viewed in the normal direction of the principal surface of the upper electrode 109 (or the lower electrode 107), all the via holes VHa are positioned to overlap the lower wiring lines 102.

Above the lower electrode 107, the via holes VHc are formed. Here, the via holes VHc connect the lower electrode 107 to the upper wiring line 106c in the same voltage as the lower electrode 107. Four via holes VHc are formed immediately above the lower wiring lines 102c (four out of six lower wiring lines 102 in the center of FIG. 4) with the same voltage as the lower electrode 107. In other words, in the lower extension of the longitudinal direction of the via holes VHc, the lower wiring lines 102c with the same voltage as the lower electrode 107 are formed. Specifically, when viewed in the normal direction of the principal surface of the upper electrode 109 (or the lower electrode 107), all the via holes VHc are positioned to overlap the lower wiring lines 102c.

Further, above the upper electrode 109, the via holes VHb are formed. Here, the via holes VHb connect the upper electrode 109 to the upper wiring line 106b with the same voltage as the upper electrode 109. Six via holes VHb are formed immediately above the lower wiring lines 102b (two out of six lower wiring lines 102 on both sides of FIG. 4) with the same voltage as the upper electrode 109. In other words, in the lower extension of the longitudinal direction of the via holes VHb, the lower wiring lines 102b with the same voltage as the upper electrode 109 are formed. Specifically, when viewed in the normal direction of the principal surface of the upper electrode 109 (or the lower electrode 107), all the via holes VHb are positioned to overlap the lower wiring lines 102b.

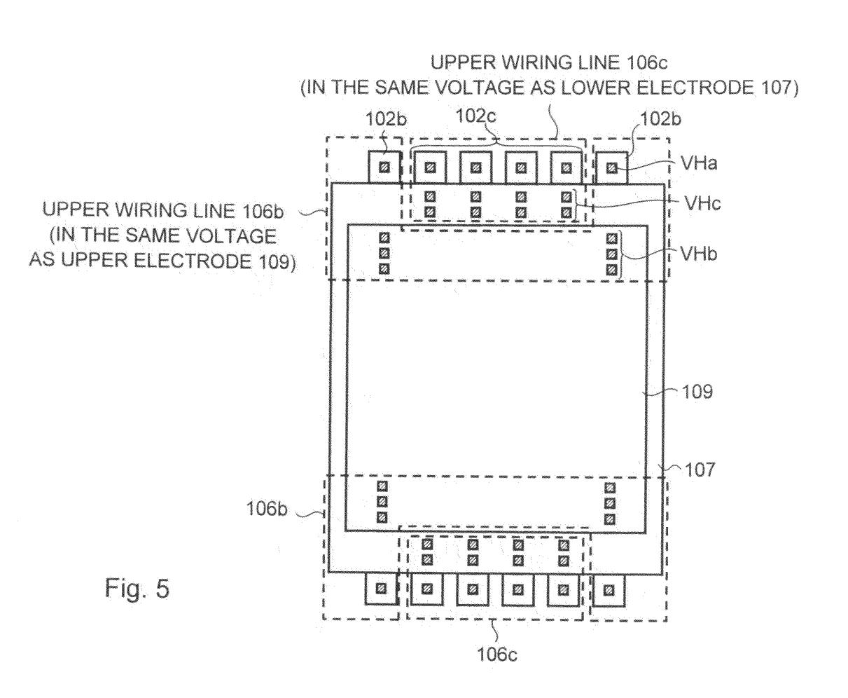

FIG. 5 is a plan layout diagram illustrating the upper wiring lines 106b and 106c overlapping FIG. 4. In addition, FIG. 1 schematically shows that the lower wiring line 102b connecting to the upper electrode 109 with the same voltage is formed in the lower extension of the longitudinal direction of the via hole VHb and that the lower wiring line 102c connecting to the lower electrode 107 with the same voltage is formed in the lower extension of the longitudinal direction of the via hole VHc. Therefore, FIG. 1 is not a particular cross-section view of FIG. 4 or FIG. 5.

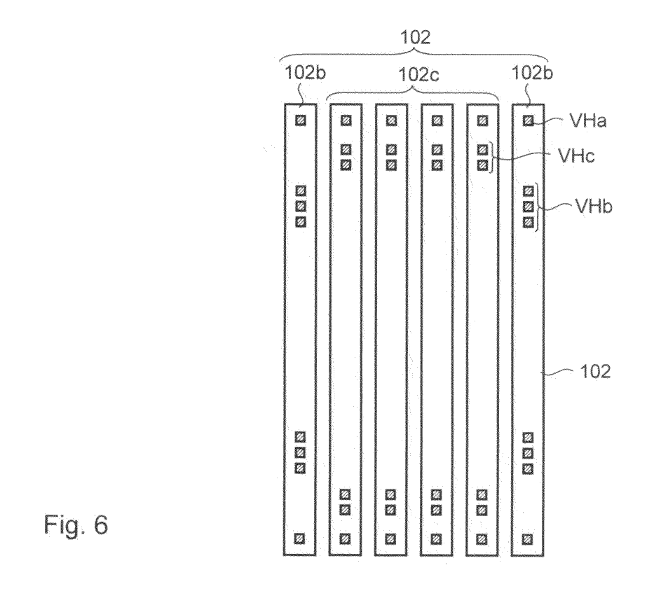

FIG. 6 is a plan layout diagram illustrating a semiconductor device including no MIM capacitor. The via hole VHc, which connects to the lower electrode 107 in the case of mounting

MIM capacitors, connects to the lower wiring line 102c with the same voltage. The via hole VHb, which connects to the upper electrode 109 in the case of mounting MIM capacitors, connects to the lower wiring line 102b with the same voltage. Even in the case of producing the semiconductor device with no MIM capacitor by using the same via hole layout mask as the semiconductor device with MIM capacitors, the via hole VHb is to connect to the lower wiring line 102b with the same voltage, or the via hole VHc is to connect to the lower wiring line 102c with the same voltage. Therefore, there is no process problem and characteristics evaluation can be performed. In other words, it is possible to provide a semiconductor device that can be evaluated efficiently while changing the number of mounted MIM capacitors.

[Second Exemplary Embodiment]

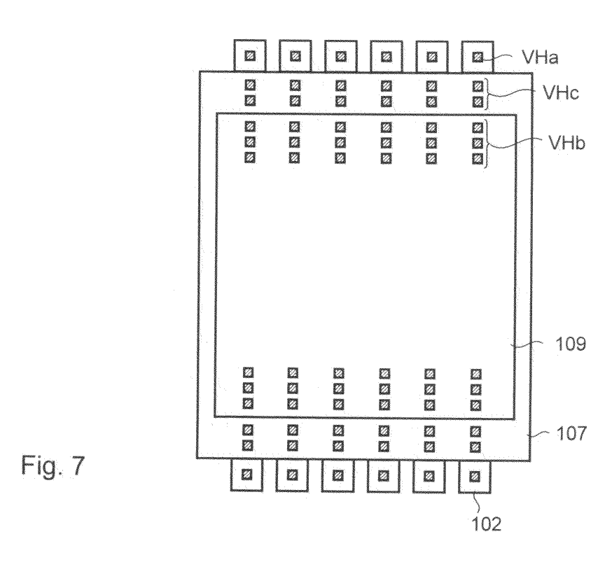

Next, a second exemplary embodiment of the present invention will be described with reference to FIG. 7. FIG. 7 is a plan layout diagram illustrating a semiconductor device according to the second exemplary embodiment of the present invention. As with FIG. 4, FIG. 7 shows a position relation among the lower wiring line 102, the lower electrode 107, the upper electrode 109, and the via holes VHa, VHb, and VHc.

In the semiconductor device according to the second exemplary embodiment of the present invention, only evaluation circuits of MIM capacitors are formed. Therefore, there is no need to take into consideration the voltage difference between the lower wiring lines 102 and the via holes VHb or VHc. Here, the lower wiring lines 102 connect to the via holes VHb and VHc in the case of mounting no MIM capacitor. Therefore, it is possible to arrange the via holes VHa, which directly connect the lower wiring lines 102 to the upper wiring lines 106, the via hole VHb connecting the upper electrode 109 to the upper wiring lines 106b, and the via holes VHc, which connect the lower electrode 107 to the upper wiring lines 106c, above all the lower wiring lines 102. Also in the second exemplary embodiment, the same effects as those of the first exemplary embodiment are obtained.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A semiconductor device comprising:
an MIM capacitor that comprises a lower electrode, an upper electrode, and a capacitor insulating film formed between the lower electrode and the upper electrode;
a first via hole that connects to the lower electrode and extends in a normal upward direction of a principal surface of the lower electrode;
a second via hole that connects to the upper electrode and extends in a normal upward direction of a principal surface of the upper electrode; and
a plurality of lower wiring lines that are formed under the lower electrode,
wherein formation areas of the first and second via holes overlap formation areas of the plurality of lower wiring lines when viewed in the normal direction of the principal surface of the upper electrode.

2. The semiconductor device according to claim 1, wherein one of the plurality of lower wiring lines and the lower electrode are in the same voltage, the one of the plurality of lower wiring lines overlapping the first via hole when viewed in the normal direction of the principal surface of the upper electrode.

3. The semiconductor device according to claim 1, wherein one of the plurality of lower wiring lines and the upper electrode are in the same voltage, the one of the plurality of lower wiring lines overlapping the second via hole when viewed in the normal direction of the principal surface of the upper electrode.

4. The semiconductor device according to claim 1, wherein the upper electrode and the lower electrode are in different voltages.

5. A layout method for a semiconductor device, the semiconductor device comprising: an MIM capacitor that comprises a lower electrode, an upper electrode, and a capacitor insulating film formed between the lower electrode and the upper electrode; a first via hole that connects to the lower electrode and extends in a normal upward direction of a principal surface of the lower electrode; a second via hole that connects to the upper electrode and extends in a normal upward direction of a principal surface of the upper electrode; and a plurality of lower wiring lines that are formed under the lower electrode, the layout method comprising:
forming the first and second via holes to overlap the plurality of lower wiring lines when viewed in the normal direction of the principal surface of the upper electrode.

6. The layout method for a semiconductor device according to claim 5, wherein one of the plurality of lower wiring lines and the lower electrode are in the same voltage, the one of the plurality of lower wiring lines overlapping the first via hole when viewed in the normal direction of the principal surface of the upper electrode.

7. The layout method for a semiconductor device according to claim 5, wherein one of the plurality of lower wiring lines and the upper electrode are in the same voltage, the one of the plurality of lower wiring lines overlapping the second via hole when viewed in the normal direction of the principal surface of the upper electrode.

8. The layout method for a semiconductor device according to claim 5, wherein the upper electrode and the lower electrode are in different voltages.
